(19) United States
(12) Patent Application Publication
(10) Pub. No.: US 2015/0069401 A1
(43) Pub. Date: Mar. 12, 2015

(54) THIN FILM TRANSISTOR SUBSTRATE AND METHOD OF MANUFACTURING THE THIN FILM TRANSISTOR SUBSTRATE

(71) Applicant: Samsung Display Co., LTD., Yongin-City (KR)

(72) Inventors: Hyun-Jae NA, Seoul (KR); Myoung-Geun CHA, Seoul (KR); Yoon-Ho KHANG, Yongin-si (KR)

(73) Assignee: Samsung Display Co., LTD., Yongin-City (KR)

(21) Appl. No.: 14/152,027

(22) Filed: Jan. 10, 2014

(30) Foreign Application Priority Data
Sep. 6, 2013 (KR) 10-2013-0106998

(51) Int. Cl. H01L 29/786; H01L 29/66

(52) U.S. Cl. CPC H01L 29/786; H01L 29/66742
USPC 257/72; 438/151

(57) ABSTRACT

A thin film transistor substrate includes a base substrate, an active pattern provided on the base substrate and including a source electrode, a drain electrode and a channel between the source electrode and the drain electrode, a gate insulation layer provided on the active pattern, a gate electrode which is provided on the active pattern and overlaps the channel, a first contact pad disposed on at least one of the source electrode and the drain electrode and including a first metal, and a first non-conductive metal oxide layer on the base substrate to cover the gate electrode and including the first metal.

This application claims priority to Korean Patent Application No. 10-2013-0106998, filed on Sep. 6, 2013, and all the benefits accruing therefrom under 35 U.S.C. §119, the contents of which are herein incorporated by reference in their entirety.

### BACKGROUND

1. Field

Exemplary embodiments relate to a thin film transistor (“TFT”) substrate and a method of manufacturing the TFT substrate. More particularly, exemplary embodiments relate to a TFT substrate including a source/drain electrode in contact with a metal contact pad and a method of manufacturing the same.

2. Description of the Related Art

Generally, a switching element such as a thin film transistor for driving a pixel in a display device includes a gate electrode, a source electrode, a drain electrode and a channel layer forming a channel between the source electrode and the drain electrode. The channel layer includes a semiconductor layer including amorphous silicon, polysilicon, oxide semiconductor or the like.

An oxide semiconductor may be formed by a low-temperature process, and may be easily large-scaled and have a relatively high electron mobility.

### SUMMARY

A source electrode and a drain electrode may make contact with and be electrically connected to a connection electrode and a pixel electrode. In this case, a contact structure capable of reducing a contact resistance between the source/drain electrode and the electrode may be beneficial.

Exemplary embodiments provide a thin film transistor (“TFT”) substrate having a contact structure capable of reducing a contact resistance on a source/drain electrode.

Exemplary embodiments provide a method of manufacturing the TFT substrate.

According to exemplary embodiments, a TFT substrate includes a base substrate, an active pattern provided on the base substrate and including a source electrode, a drain electrode and a channel between the source electrode and the drain electrode, a gate insulation layer provided on the active pattern, a gate electrode which is provided on the active pattern and overlaps the channel, a first contact pad disposed on at least one of the source electrode and the drain electrode and including a first metal, and a first non-conductive metal oxide layer on the base substrate to cover the gate electrode and including the first metal.

In exemplary embodiments, the TFT substrate may further include a second contact pad provided on the first contact pad and including a second metal having an etch selectivity with respect to the first metal.

In exemplary embodiments, the TFT substrate may further include a second non-conductive metal oxide layer provided on a sidewall of the second contact pad and including the second metal.

In exemplary embodiments, the first contact pad may have a first thickness and the second contact pad may have a second thickness greater than the first thickness.

In exemplary embodiments, the first and second non-conductive metal oxide layers include a plasma oxidation treated or a thermal-oxidation-treated first and second metals, respectively.

In exemplary embodiments, the first metal may include aluminum or titanium.

In exemplary embodiments, the TFT substrate may further include a data line electrically connected to the source electrode.

In exemplary embodiments, the data line may include at least one of the first metal and a second metal.

In exemplary embodiments, the TFT substrate may further include an organic insulation layer which covers the first non-conductive metal oxide layer.

In exemplary embodiments, the first contact pad may contact the source electrode.

In exemplary embodiments, the TFT substrate may further include a connection electrode electrically connecting the first contact pad and a data line.

In exemplary embodiments, the first contact pad may contact the drain electrode.

In exemplary embodiments, the TFT substrate may further include a pixel electrode which electrically connects to the first contact pad.

According to exemplary embodiments, in a method of manufacturing a method of manufacturing a TFT substrate, a semiconductor pattern is disposed on a base substrate. A gate insulation layer pattern and a gate electrode are disposed on the semiconductor pattern, a portion of the semiconductor pattern being exposed by the gate insulation layer pattern and the gate electrode. An exposed portion of the semiconductor pattern is reduced to provide a source electrode and a drain electrode. A first data metal layer is disposed on the base substrate to cover the gate electrode, the source electrode and the drain electrode, the first data metal layer including a first metal. An oxidation treatment is selectively performed on the first data metal layer to provide a first non-conductive metal oxide layer on the gate electrode and a first contact pad on at least one of the source electrode and the drain electrode.

In exemplary embodiments, the selectively performing an oxidation treatment on the first data metal layer may include disposing a second data metal layer on the first data metal layer, the second data metal layer including a second metal having an etch selectivity with respect to the first metal, patterning the second data metal layer to provide a second data metal pattern on a region at which the first contact pad is to be provided, and oxidizing the exposed portion of the first data metal layer to provide the first non-conductive metal layer and the first contact pad together.

In exemplary embodiments, the first data metal layer may have a first thickness and the second data metal layer may have a second thickness greater than the first thickness.

In exemplary embodiments, oxidizing the exposed portion of the first data metal layer may include performing a plasma oxidation treatment or a thermal oxidation treatment.

In exemplary embodiments, patterning the second data metal layer may include disposing a mask on the second data metal layer to cover a region at which the first contact pad is to be provided, and selectively removing the second data metal layer using the mask to provide the second data metal pattern.

In exemplary embodiments, oxidizing the exposed portion of the first data metal layer may include oxidizing the exposed portion of the second data metal pattern to provide a second non-conductive metal oxide layer.

In exemplary embodiments, the method may further include an organic insulation layer covering the first non-conductive metal oxide layer

According to exemplary embodiments, a source electrode and a drain electrode including a reduced metal oxide semiconductor such as indium gallium zinc oxide (“IGZO”) may be electrically connected to a connection electrode and a pixel electrode by contact pads including metal, thereby reducing a contact resistance on the source/drain electrode.

Further, a data metal line and a passivation layer may be provided together using first and second data metal layers having an etch selectivity with respect to each other, thereby reducing the number of masks used in manufacturing a display substrate.

### BRIEF DESCRIPTION OF THE DRAWINGS

Exemplary embodiments will be more clearly understood from the following detailed description taken in conjunction with the accompanying drawings. FIGS. 1 to 14 represent non-limiting, exemplary embodiments as described herein.

FIG. 1 is a plan view illustrating an exemplary embodiment a thin film transistor (“TFT”) substrate in accordance with the invention.

FIG. 2 is a cross-sectional view taken along line I-I′ line in FIG. 1.

FIGS. 3 to 10 are cross-sectional views illustrating an exemplary embodiment of a method of manufacturing a TFT substrate in accordance with the invention.

FIGS. 11 to 14 are cross-sectional views illustrating an exemplary embodiment of a method of manufacturing a TFT substrate in accordance with the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, exemplary embodiments will be explained in detail with reference to the accompanying drawings.

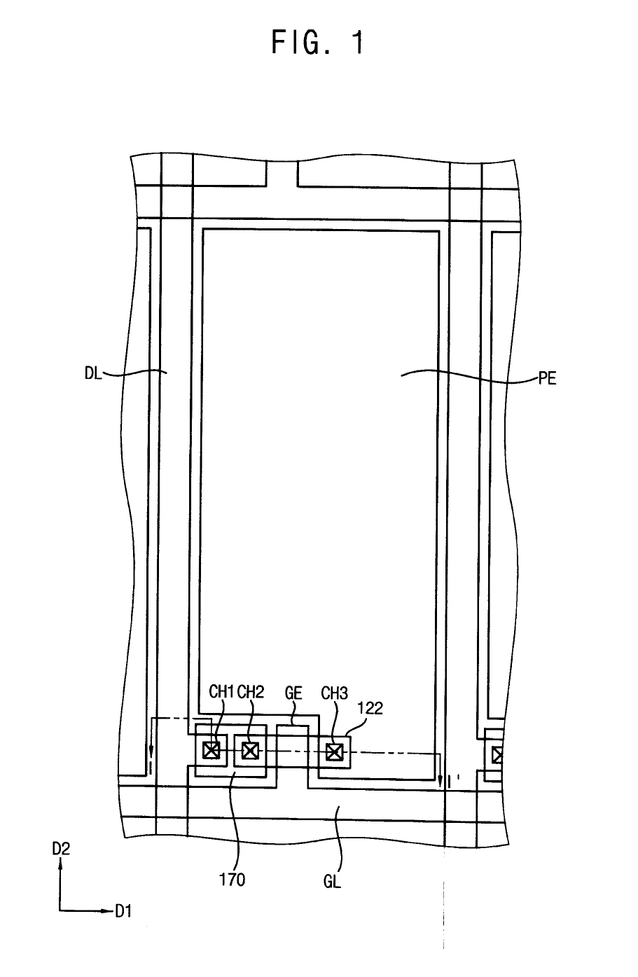

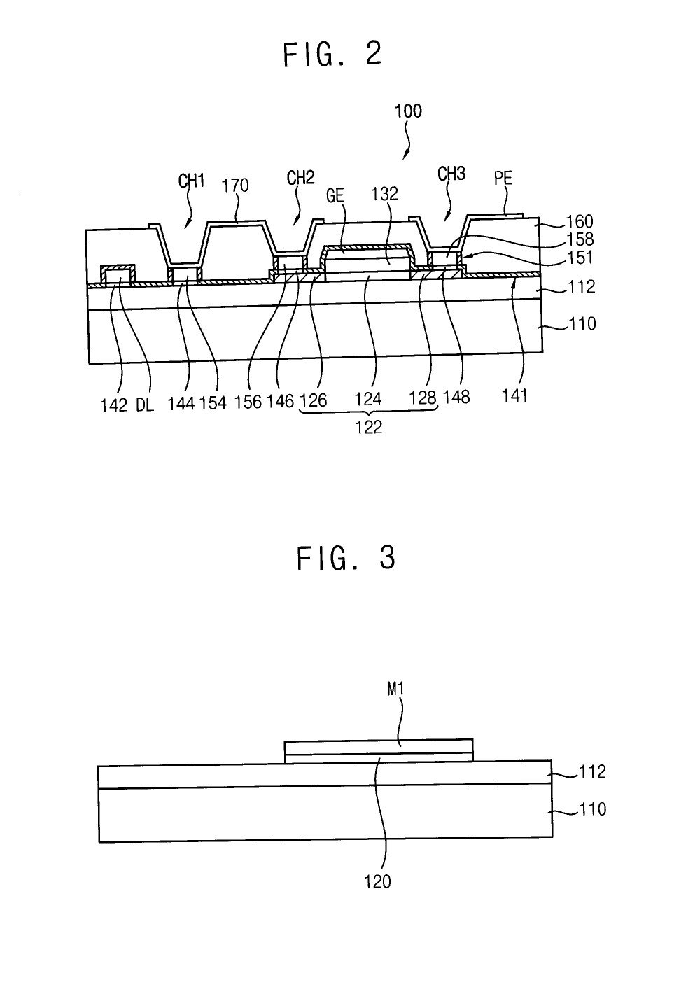

FIG. 1 is a plan view illustrating a thin film transistor (“TFT”) substrate in accordance with exemplary embodiments. FIG. 2 is a cross-sectional view taken along line I-I′ line in FIG. 1.

Referring to FIGS. 1 and 2, a TFT substrate 100 may include a base substrate 110, a gate line GL, a data line DL and an active pattern 122.

The gate line GL may extend in a first direction (D1) on the base substrate 110. The data line DL may extend in a second direction (D2) crossing the first direction (D1) on the base substrate 110. In an exemplary embodiment, the first direction (D1) may be substantially perpendicular to the second direction (D2), for example.

The gate line GL may be electrically connected to the gate electrode GE. In an exemplary embodiment, the gate electrode GE may extend from the gate line GL in the second direction (D2), for example.

The active pattern 122 may include a channel 124, a source electrode 126 and a drain electrode 128. In an exemplary embodiment, the channel 124, the source electrode 126 and the drain electrode 128 may be provided in and/or on a same layer. The channel 124 may be disposed between the source electrode 126 and the drain electrode 128.

The channel 124 may overlap with the gate electrode GE. The gate electrode GE may be disposed on the channel 124. A gate insulation layer pattern 132 may be disposed between the gate electrode GE and the channel. 124. The gate electrode GE may cover entirely the channel 124.

The TFT substrate 100 may further include a pixel electrode PE electrically connected to the drain electrode 128.

The data line DL may be provided on the base substrate 110 to be electrically connected to the source electrode 126. As mentioned later, the data line DL may be electrically connected to the source electrode 126 by a connection electrode 170.

The gate electrode GE, the channel 124, the source electrode 126 and the drain electrode 128 may provide a TFT. When a gate signal may be transferred to the gate electrode GE through the gate line GL, the channel 124 may have conductivity, and thus, a data signal from the data line DL may be transferred to the pixel electrode PE through the connection electrode 170, the source electrode 126, the channel 124 and the drain electrode 128.

The TFT substrate 100 may further include first and second passivation layers 141 and 151 covering the TFT and the data line, and an organic insulation layer 160 covering the first and second passivation layers 141 and 151. The pixel electrode PE and the connection electrode 170 may be disposed on the organic insulation layer 160.

In exemplary embodiments, the TFT substrate 100 may include a contact pad 142, a first contact pad 146/156 disposed on the source electrode 126, a second contact pad 148/158 disposed on the drain electrode 128, and a data contact pad 144/154 disposed on an extending portion of the data line DL.

In an exemplary embodiment, the contact pad 142 may be disposed on the base substrate 110, and the data line DL may be disposed on the contact pad 142.

The first contact pad may include a first source contact pad 146 on the source electrode 126 and a second source contact pad 156 on the first source contact pad 146.

The second contact pad may include a first drain contact pad 148 on the drain electrode 128 and a second drain contact pad 158 on the first drain contact pad 148.

The third contact pad may include a first data contact pad 144 on the extending portion of the data line DL and a second data contact pad 154 on the first data contact pad 144.

The first source contact pad 146, the first drain contact pad 148 and the first data contact pad 144 may include a first metal. The second source contact pad 156, the second drain contact pad 158 and the second data contact pad 154 may include a second metal. The first metal may have an etch selectivity with respect to the second metal.

In an exemplary embodiment, the first metal may be transformed by a plasma oxidation treatment or a thermal oxidation treatment, for example, into a first metal oxide having non-conductivity. In an exemplary embodiment, the second metal may be transformed by a plasma oxidation treatment or a thermal oxidation treatment, for example, into a second metal oxide having non-conductivity. In an exemplary embodiment, the first metal may include aluminum, titanium, etc., and the second metal may include copper, etc.

The first passivation layer 141 may include a first non-conductive metal oxide layer that is provided by oxidizing a portion of a first metal layer including the first metal. The first passivation layer 141 may be provided on the base substrate 110 to cover the gate electrode GE. The second passivation layer 151 may include a second non-conductive metal oxide layer that is provided by oxidizing a portion of a second metal layer including the second metal.

The data line DL may be provided in and or on the same metal layer as the contact pad. The data line DL may include the same material as that of the first contact pad, the second contact pad and the data contact pad. In an exemplary embodiment, the data line DL may include at least one of the first metal and the second metal.

The connection electrode 170 may contact the second data contact pad 154 through a first contact hole CH1 and contact the second source contact pad 156 through a second contact hole CH2. Accordingly, the data line DL may be electrically connected to the source electrode 126 by the connection electrode 170.

Further, the pixel electrode PE may contact the second drain contact pad 158 through a third contact hole CH3. Accordingly, the pixel electrode PE may be electrically connected to the data electrode 128.

Hereinafter, a method of manufacturing the TFT substrate in FIG. 1 will be explained in detail.

FIGS. 3 to 10 are cross-sectional views illustrating an exemplary embodiment of a method of manufacturing a TFT substrate in accordance with the invention.

Referring to FIG. 3, a buffer layer 112 may be disposed on a base substrate 110 and a semiconductor pattern 120 may be disposed on the buffer layer 112.

In exemplary embodiments, a semiconductor layer (not illustrated) may be disposed on the buffer layer 112, and then, may be patterned to provide the semiconductor pattern 120. In particular, after a first photoresist pattern M1 is disposed on the semiconductor layer, the semiconductor layer may be etched using the first photoresist pattern M1 as an etching mask to provide the semiconductor pattern 120. Then, the first photoresist pattern M1 may be removed from the base substrate 110.

In an exemplary embodiment, the base substrate 110 may include a glass substrate, a quartz substrate, a silicon substrate, a plastic substrate, etc. The buffer layer 112 may include silicon oxide, aluminum oxide, hafnium oxide, yttrium oxide, etc. The buffer layer 112 may have a thickness of about 500 angstrom (Å) to about 1,000 Å.

The semiconductor layer may include metal oxide semiconductor. In an exemplary embodiment, the metal oxide semiconductor may include an oxide of zinc, indium, gallium, tin, titanium, phosphor, or combination thereof. In an exemplary embodiment, the metal oxide semiconductor may include at least one of zinc oxide (“ZnO”), zinc tin oxide (“ZTO”), zinc indium oxide (“ZIO”), indium oxide (“InO”), titanium oxide (“TiO”), indium gallium zinc oxide (“IGZO”), and indium zinc tin oxide (“IZTO”).

In an exemplary embodiment, the buffer layer and the semiconductor layer may be provided by a chemical vapor deposition (“CVD”) process, a plasma enhanced chemical vapor deposition (“PECVD”) process, a solution coating process, a sputtering process, or the like.

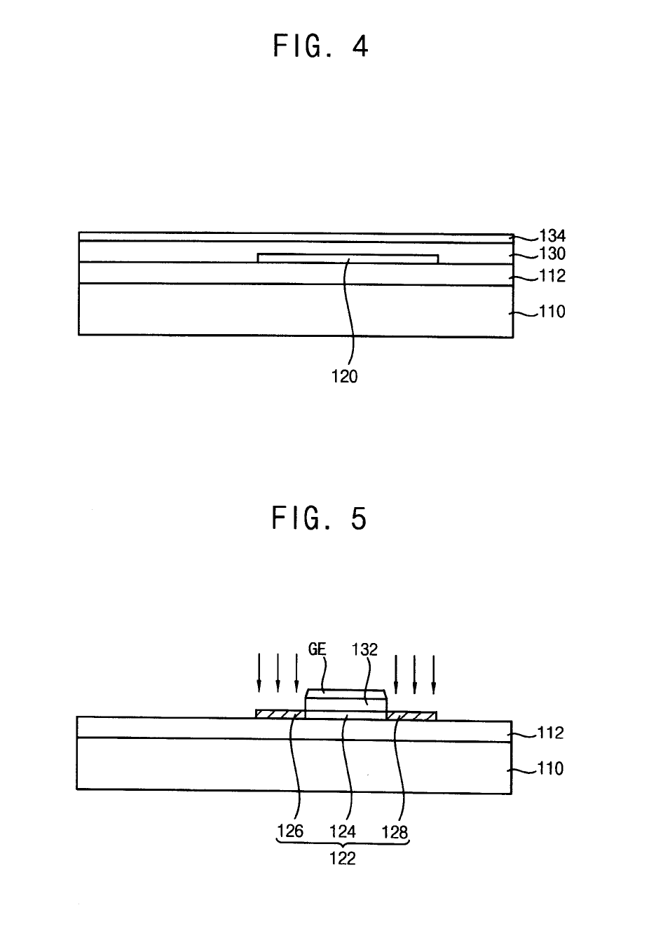

Referring to FIG. 4, a gate insulation layer 130 and a gate metal layer 134 may be disposed on the semiconductor pattern 120.

The gate insulation layer 130 may be disposed on the buffer layer 112 to cover the semiconductor pattern 120. The gate insulation layer 130 may have a single-layer structure or a multi-layered structure. In an exemplary embodiment, the gate insulation layer 130 may include silicon nitride, silicon oxide, etc.

In an exemplary embodiment, the gate insulation layer 130 may have a lower gate insulation layer and an upper gate insulation layer. The lower gate insulation layer may be disposed on the semiconductor pattern 120 and the upper gate insulation layer may be disposed on the lower gate insulation layer. In this case, the lower gate insulation layer may include silicon oxide, aluminum oxide, hafnium oxide, yttrium oxide, etc. In an exemplary embodiment, the lower gate insulation layer may have a thickness of about 500 Å to about 3,000 Å, for example. In an exemplary embodiment, the upper gate insulation layer may have a thickness of about 500 Å to about 2,000 Å, for example.

In an exemplary embodiment, the gate metal layer 134 may include copper, silver, chromium, molybdenum, aluminum, titanium, manganese or an alloy thereof. The gate metal layer 134 may have a single-layered structure or a multi-layered structure including a plurality of metal layers having different materials. In an exemplary embodiment, the gate metal layer 134 may include a copper layer and a titanium layer disposed above and/or under the copper layer, for example.

In an alternative exemplary embodiment, the gate metal layer may include a metal layer and an oxide layer disposed above and/or under the metal layer. In an exemplary embodiment, the gate metal layer may include a copper layer, and an oxide layer disposed above and/or under the copper layer, for example. In an exemplary embodiment, the oxide layer may include at least one of indium zinc oxide, indium tin oxide, gallium zinc oxide, zinc aluminum oxide or any combinations thereof.

Referring to FIG. 5, after the gate metal layer 134 and the gate insulation layer 130 are patterned to provide a gate electrode (GE), a gate line (GL, see FIG. 1) and a gate insulation layer pattern 132, the semiconductor pattern 120 may be changed to provide an active pattern 122 including a channel 124, a source electrode 126 and a drain electrode 128.

First, the gate metal layer 134 may be patterned using a second mask to provide the gate electrode GE and the gate line GL, and then, the gate insulation layer 130 may be patterned using the gate electrode GE and the gate line GL as a mask to from the gate insulation layer pattern 132. Accordingly, the gate insulation layer pattern 132 may have a shape corresponding to the gate line GL and the gate electrode GE.

A portion of the semiconductor pattern 120 may be exposed in the process of patterning the gate insulation layer 130 to provide the gate insulation layer pattern 132. However, since the gate insulation layer 130 includes a material different from that of the semiconductor pattern 120, the gate insulation layer 130 has an etch selectivity with respect to the semiconductor pattern 120. Accordingly, the semiconductor pattern 120 may not be etched in the process of patterning the gate insulation layer 130.

In an alternative exemplary embodiment, the gate metal layer 134 and the gate insulation layer 130 may be sequentially patterned to provide the gate electrode GE, the gate line GL and the gate insulation layer pattern 132 together.

Then, the channel 124, the source electrode 126 and the drain electrode 128 may be provided from the semiconductor pattern 120. Particularly, a portion of the semiconductor pattern 120 which exposed by the gate electrode GE and the gate insulation layer pattern 132, may be changed to the source electrode 126 and the drain electrode 128.

Then, the semiconductor pattern 120 may be plasma-treated to provide the source electrode 126 and the drain electrode 128. In an exemplary embodiment, the exposed portion of the semiconductor pattern 120 may be provided with a plasma gas PT indicated by the downward arrows in FIG. 5, of H₂, He, PH3, NH₃, SiH₄, CH₄, C₂H₂, B₂H₆, CO₂, GeH₄, H₂Se, H₂S, Ar, N₂, N₂O, CHF₃ or the like. Accordingly, at least a portion of a semiconductor material included in the semiconductor pattern 120 may be reduced to provide a metallic conductor. As a result, the reduced portion of the semiconductor pattern 120 may provide the source electrode 126 and the drain electrode 128, and a portion of the semiconductor pattern 120 which is covered by the gate electrode GE and the gate insulation layer pattern 132, remains to function as the channel 124.

In an alternative exemplary embodiment, the semiconductor pattern 120 may be heated in an atmosphere of a reducing gas or may be ion-implanted to provide the active pattern 122.

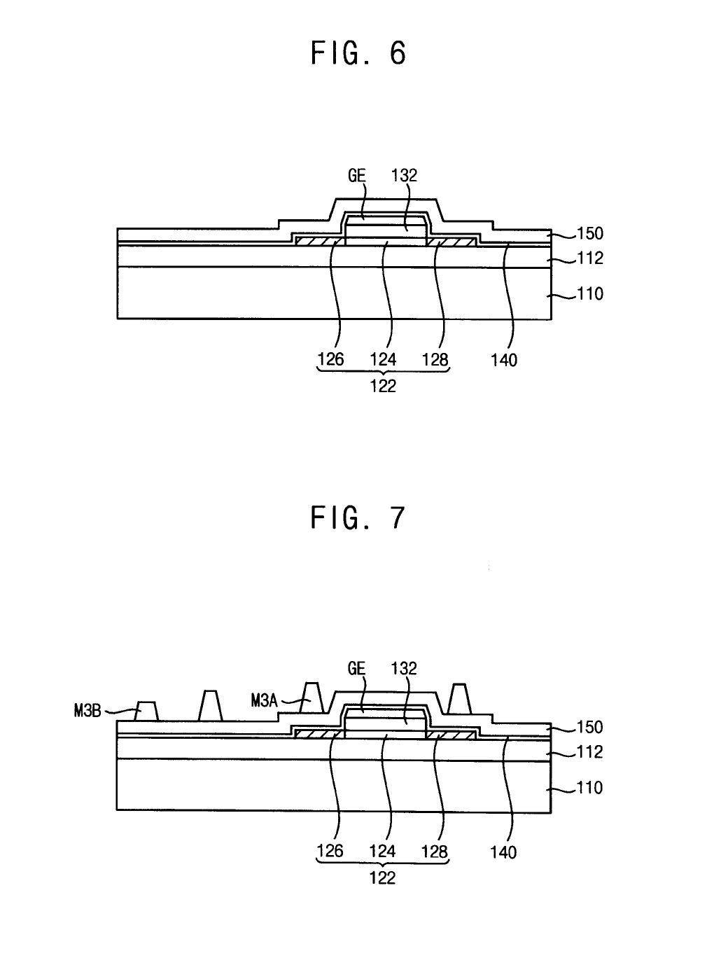

Referring to FIG. 6, a data metal layer may be disposed on the buffer layer 112. The data metal layer may include a first data metal layer 140 and a second data metal layer 150. The first data metal layer 140 may be disposed on the buffer layer 112 to cover the gate electrode GE, the source electrode 126 and the drain electrode 128. The second data metal layer 150 may be disposed on the first data metal layer 140. In an exemplary embodiment, the first and second data metal layers 140 and 150 may be provided by a sputtering process.

The first metal layer 140 may include a first metal and the second metal layer 150 may include a second metal having an etch selectivity with respect to the first metal. The first metal may be changed by an oxidation treatment to be non-conductive. The second metal may be changed by an oxidation treatment to be non-conductive.

In an exemplary embodiment, the first metal may be transformed by a plasma oxidation treatment or a thermal oxidation treatment into a first metal oxide having non-conductivity, for example. The second metal may be transformed by a plasma oxidation treatment or a thermal oxidation treatment into a second metal oxide having non-conductivity.

Examples of the first metal may be aluminum, titanium, etc. Examples of the second metal may be copper, etc. The first data metal layer 140 may have a first thickness, and the second data metal layer 150 may have a second thickness. In an exemplary embodiment, the first data metal layer 140 may have the first thickness of about 50 Å to about 500 Å, for example. In an exemplary embodiment, the second data metal layer 150 may have the second thickness of about 1,000 Å to about 3,000 Å, for example.

Referring to FIG. 7, a third mask M3A for providing a contact pad and a third mask M3B for providing a data line DL may be disposed on the data metal layer.

In an exemplary embodiment, the third mask may include a halftone mask, a slit mask or a reflow mask. The third mask M3B for providing a data line DL may have a height smaller than a height of the third mask M3A for providing a contact pad.

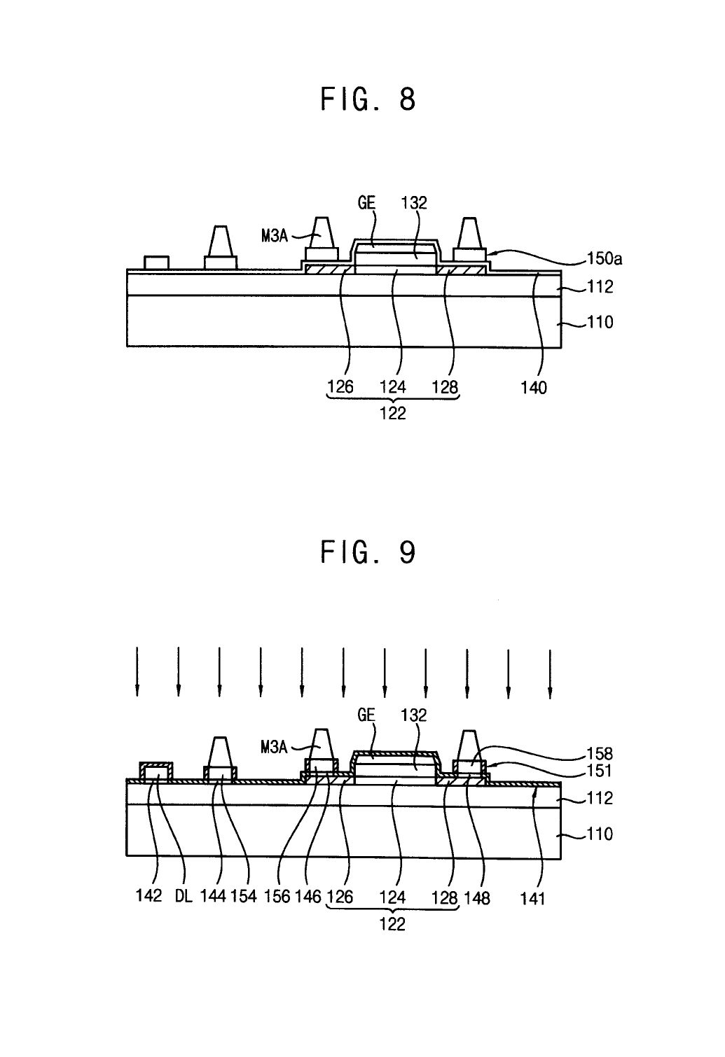

Referring to FIG. 8, the second data metal layer 150 may be selectively removed to provide second data metal patterns 150a.

The second data metal layer 150 may be patterned using the third masks M3A and M3B to provide the second data metal patterns 150a. In an exemplary embodiment, the second data metal patterns 150a may be provided by a wet etching process, for example. Since the first data metal layer 140 has an etch selectivity with respect to the second data metal layer 150, the first data metal layer 140 may not be etched by an etching solution to remain on the base substrate 110. Accordingly, the second data metal patterns 150a may be disposed on the first data metal layer 140.

The third mask M3B for providing a data line DL may be completely removed by the etching process to completely expose the second data metal pattern 150a. In another exemplary embodiment, the third mask M3A for providing a contact pad may be partially removed by the etching process to partially expose a sidewall and an upper portion of the second data metal pattern 150a.

Referring to FIG. 9, the exposed the second data metal patterns 150a and the exposed first metal data layer 140 may be oxidation-treated to provide a passivation layer.

In exemplary embodiments, the exposed second data metal pattern and the exposed first data metal pattern may be oxidized by a plasma oxidation treatment using an oxygen gas. After performing the oxidation treatment, the third mask M3A may be removed from the base substrate 110.

The exposed first data metal layer may be oxidized to be transformed into a first metal oxide layer having non-conductivity to provide a first passivation layer 141. A portion of the exposed second data metal pattern may be oxidized to be transformed into a second metal oxide layer having non-conductivity to provide a second passivation layer 151.

Since the second data metal layer has the second thickness greater than the first thickness of the first data metal layer, the first data metal layer may be completely oxidized by the oxidation treatment to provide the first passivation layer 141 and the portions of the sidewall and the upper portion of the second data metal pattern may be partially oxidized by the oxidation treatment to provide the second passivation layer 151.

As illustrated in FIG. 9, a portion of the first data metal layer under the second data metal pattern may not be oxidized to provide a first contact pad 144, 146, 148. A portion of the second data metal pattern covered by the third mask M3A may not be oxidized to provide a second contact pad 154, 156, 158.

In particular, a first source contact pad 146 and a second source contact pad 156 may be disposed sequentially on the source electrode 126. A first drain contact pad 148 and a second drain contact pad 158 may be disposed sequentially on the drain electrode 128. The first source contact pad 146 may contact the source electrode 126. The first drain contact pad 148 may contact the drain electrode 128.

The portion of the exposed second data metal pattern may not be oxidized to provide a data line DL. An extending portion of the data line DL may include a first data contact pad 144 and a second data contact pad 154 sequentially disposed on each other.

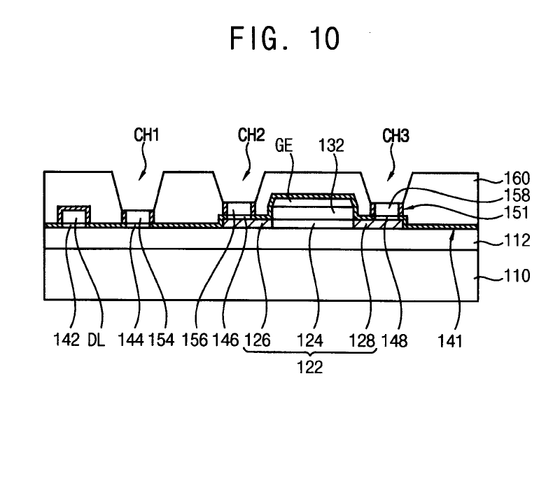

Referring to FIG. 10, after an organic insulation layer 160 is disposed on the gate electrode GE, the source electrode 126, the drain electrode 128, the first passivation layer 141, the second passivation layer 151 and the second contact pad 154, 156, 158, the organic insulation layer 160 may be patterned to define contact holes CH1, CH2 and CH3.

The organic insulation layer 160 may be using a photoresist material by a spin coating process. The organic insulation layer 160 may serve as a planarization layer for the TFT substrate.

The organic insulation layer 160 may be patterned to define a first contact hole CH1 that exposes the second data contact pad 154 of the extending portion of the data line DL, a second contact hole CH2 that exposes the second source contact pad 156 and a third contact hole CH3 that exposes the second drain contact pad 158.

Then, as illustrated in FIG. 2, a transparent conductive layer may be disposed on the organic insulation layer 160. The transparent conductive layer may include at least one of IZO and ITO.

The transparent conductive layer may be patterned to provide a connection electrode 170 and a pixel electrode PE. The connection electrode 170 may be connected to the second data contact pad 154 through the first contact hole CH1 and connected to the second source contact pad 156 through the second contact hole CH2. Accordingly, the data line DL may be electrically connected to the source electrode 126 by the connection electrode 170.

The pixel electrode PE may be connected to the second drain contact pad 158 through the third contact hole CH3.

As mentioned above, the source electrode 126 and the drain electrode 128 including a reduced metal oxide semiconductor such as IGZO may be electrically connected to the connection electrode 170 and the pixel electrode PE by the contact pads including metal, thereby reducing a contact resistance on the source/drain electrode.

Further, the data metal line and the passivation layer may be provided together using the first and second data metal layers having an etch selectivity with respect to each other, thereby reducing the number of masks used in manufacturing the display substrate.

A TFT substrate in accordance with exemplary embodiments may be used for an array substrate of a liquid crystal display device, but is not limited thereto. In an exemplary embodiment, for example, the TFT substrate may be used for another display device such as an organic electroluminescent (“EL”) display device, a circuit substrate having a TFT, a semiconductor device or the like.

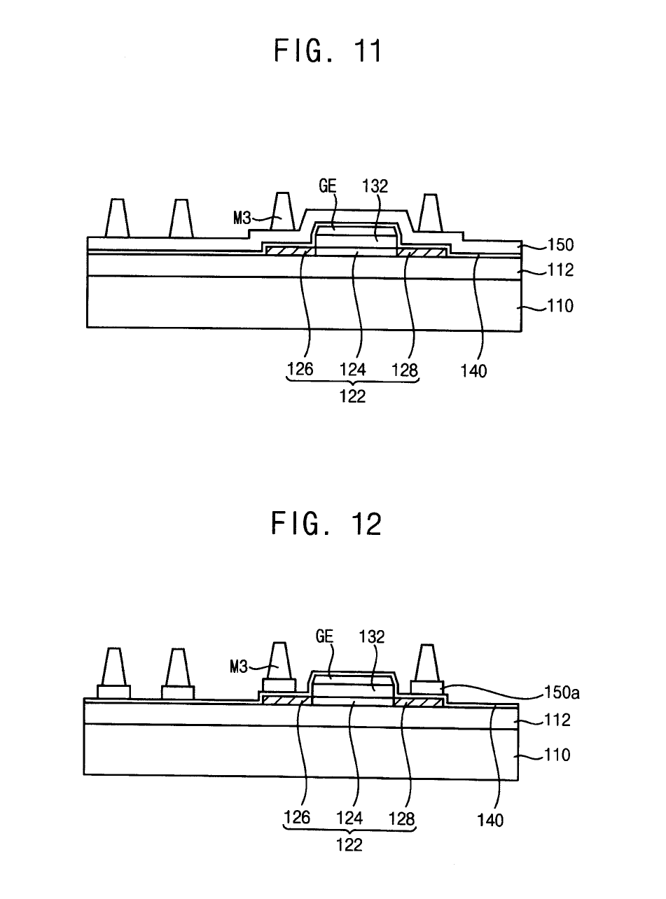

FIGS. 11 to 14 are cross-sectional views illustrating a method of manufacturing a TFT substrate in accordance with exemplary embodiments. The method may be substantially the same as or similar to the method of the TFT substrate described with reference to FIGS. 3 to 10. Thus, same reference numerals will be used to refer to the same or like elements as those described with reference to FIGS. 3 to 10, any further repetitive explanation concerning the above elements will be omitted.

Referring to FIG. 11, first, the processes described with reference to FIGS. 3 to 6 may be performed to provide a data metal layer on a buffer layer 112 on a base substrate 110, and then, a third mask M3 for providing a contact pad and a data line DL may be disposed on the data metal layer.

The data metal layer may include a first data metal layer 140 and a second data metal layer 150. The first data metal layer 140 may be disposed on the buffer layer 112 to cover a gate electrode GE, a source electrode 126 and a drain electrode 128. The second data metal layer 150 may be disposed on the first data metal layer 140.

The first metal layer 140 may include a first metal and the second metal layer 150 may include a second metal having an etch selectivity with respect to the first metal. The first metal may be changed by an oxidation treatment to have non-conductivity. The second metal may be changed by an oxidation treatment to have non-conductivity.

In an exemplary embodiment, the first metal may be transformed by a plasma oxidation treatment or a thermal oxidation treatment into a first metal oxide having non-conductivity. The second metal may be transformed by a plasma oxidation treatment or a thermal oxidation treatment into a second metal oxide having non-conductivity.

In this exemplary embodiment, the third mask M3 for providing a contact pad may have the same height as the third mask M3 for providing a data line DL.

Referring to FIG. 12, the second data metal layer 150 may be partially removed to provide second data metal patterns 150a.

The second data metal layer 150 may be patterned using the third masks M3 to provide the second data metal patterns 150a. The second data metal patterns 150a may be provided by a wet etching process. Since the first data metal layer 140 has an etch selectivity with respect to the second data metal layer 150, the first data metal layer 140 may not be etched by an etching solution to remain on the base substrate 110. Accordingly, the second data metal patterns 150a may be disposed on the first data metal layer 140.

The third mask M3 for providing a contact pad and a data line DL may be partially consumed by the etching process to partially expose a sidewall and an upper portion of the second data metal pattern 150a.

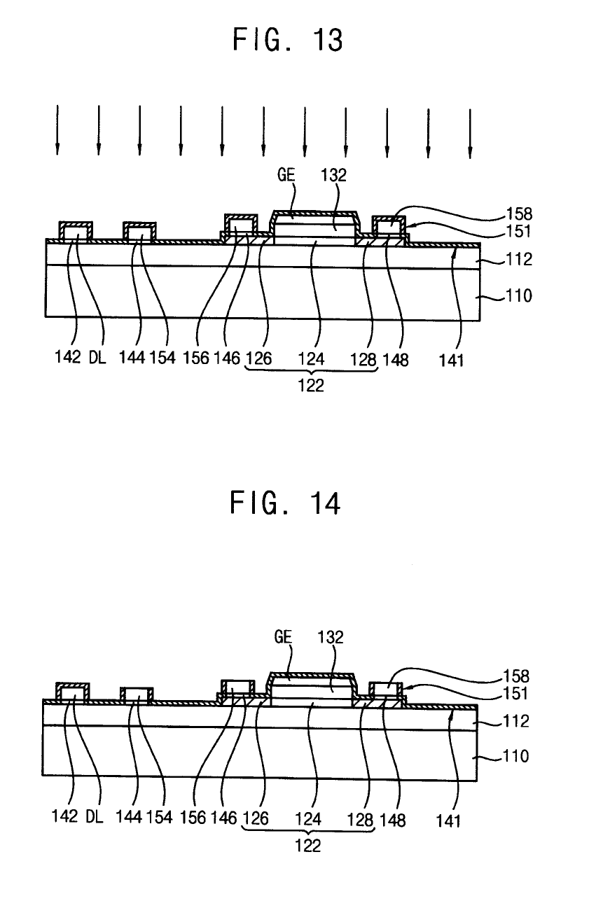

Referring to FIG. 13, after removing the third mask M3, the exposed the second data metal patterns 150a and the exposed first metal data layer 140 may be oxidation-treated to provide a passivation layer.

In this exemplary embodiment, the exposed the second data metal patterns and the exposed first metal data layer may be oxidized under an oxygen atmosphere by a thermal oxidation treatment.

The exposed first data metal layer may be oxidized to be transformed into a first metal oxide layer having non-conductivity to provide a first passivation layer 141. A portion of the exposed second data metal pattern may be oxidized to be transformed into a second metal oxide layer having non-conductivity to provide a second passivation layer 151.

Since the second data metal layer has a second thickness greater than a first thickness of the first data metal layer, the first data metal layer may be completely oxidized by the oxidation treatment to provide the first passivation layer 141 and the exposed portions of the sidewall and the upper portion of the second data metal pattern may be partially oxidized by the oxidation treatment to provide the second passivation layer 151.

As illustrated in FIG. 13, a portion of the first data metal layer under the second data metal pattern may not be oxidized to provide a first contact pad 144, 146, 148. A portion of the second data metal pattern covered by the third mask M3 may not be oxidized to provide a second contact pad 154, 156, 158.

In particular, a first source contact pad 146 and a second source contact pad 156 may be disposed sequentially on the source electrode 126. A first drain contact pad 148 and a second drain contact pad 158 may be disposed sequentially on the drain electrode 128. The first source contact pad 146 may contact the source electrode 126. The first drain contact pad 148 may contact the drain electrode 128.

The portion of the exposed second data metal pattern may not be oxidized to provide a data line DL. An extending portion of the data line DL may include a first data contact pad 144 and a second data contact pad 154 sequentially disposed on each other.

Referring to FIG. 14, portions of the second passivation layer 151 on the second source contact pad 156, the second contact pad 158 and the second data contact pad 154 may be removed from the base substrate 110.

In an exemplary embodiment, a fourth mask (not illustrated) may be disposed on the first and second passivation layers 141 and 151, and then, the portions of the second passivation layer 151 on the second source contact pad 156, the second contact pad 158 and the second data contact pad 154 may be removed using the fourth mask, to expose upper surfaces of the second source contact pad 156, the second contact pad 158 and the second data contact pad 154.

Then, the processes described with reference to FIG. 10 may be performed to provide the TFT substrate in FIG. 2.

The foregoing is illustrative of exemplary embodiments and is not to be construed as limiting thereof. Although a few exemplary embodiments have been described, those skilled in the art will readily appreciate that many modifications are possible in exemplary embodiments without materially departing from the novel teachings and advantages of the invention. Accordingly, all such modifications are intended to be included within the scope of exemplary embodiments as defined in the claims. In the claims, means-plus-function clauses are intended to cover the structures described herein as performing the recited function and not only structural equivalents but also equivalent structures. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. A thin film transistor substrate, comprising:
a base substrate;
an active pattern provided on the base substrate and including a source electrode, a drain electrode and a channel between the source electrode and the drain electrode;
a gate insulation layer provided on the active pattern;
a gate electrode which is provided on the active pattern and overlaps the channel;
a first contact pad disposed on at least one of the source electrode and the drain electrode and including a first metal; and
a first non-conductive metal oxide layer on the base substrate to cover the gate electrode and including the first metal.

2. The thin film transistor substrate of claim 1, further comprising a second contact pad provided on the first contact pad and including a second metal having an etch selectivity with respect to the first metal.

3. The thin film transistor substrate of claim 2, further comprising a second non-conductive metal oxide layer provided on a sidewall of the second contact pad and including the second metal.

4. The thin film transistor substrate of claim 2, wherein the first contact pad has a first thickness and the second contact pad has a second thickness greater than the first thickness.

5. The thin film transistor substrate of claim 3, wherein the first and second non-conductive metal oxide layers include a plasma oxidation treated or a thermal oxidation treated first and second metals, respectively.

6. The thin film transistor substrate of claim 1, wherein the first metal comprises aluminum or titanium.

7. The thin film transistor substrate of claim 1, further comprising a data line electrically connected to the source electrode.

8. The thin film transistor substrate of claim 7, wherein the data line comprises at least one of the first metal and a second metal.

9. The thin film transistor substrate of claim 1, further comprising an organic insulation layer which covers the first non-conductive metal oxide layer.

10. The thin film transistor substrate of claim 1, wherein the first contact pad contacts the source electrode.

11. The thin film transistor substrate of claim 10, further comprising:
a data line, and
a connection electrode which electrically connects the first contact pad and the data line.

12. The thin film transistor substrate of claim 1, wherein the first contact pad contacts the drain electrode.

13. The thin film transistor substrate of claim 12, further comprising a pixel electrode electrically connected to the first contact pad.

14. A method of manufacturing a thin film transistor substrate, compressing
disposing a semiconductor pattern on a base substrate;
disposing a gate insulation layer pattern and a gate electrode on the semiconductor pattern, a portion of the semiconductor pattern being exposed by the gate insulation layer pattern and the gate electrode;
reducing the exposed portion of the semiconductor pattern to provide a source electrode and a drain electrode;
disposing a first data metal layer on the base substrate to cover the gate electrode, the source electrode and the drain electrode, the first data metal layer including a first metal; and
selectively performing an oxidation treatment on the first data metal layer to provide a first non-conductive metal oxide layer on the gate electrode and a first contact pad on at least one of the source electrode and the drain electrode.

15. The method of claim 14, wherein the selectively performing an oxidation treatment on the first data metal layer comprises:
disposing a second data metal layer on the first data metal layer, the second data metal layer including a second metal having an etch selectivity with respect to the first metal;
patterning the second data metal layer to provide a second data metal pattern on a region at which the first contact pad is to be provided; and
oxidizing an exposed portion of the first data metal layer to provide the first non-conductive metal layer and the first contact pad together.

16. The method of claim 15, wherein the first data metal layer has a first thickness and the second data metal layer has a second thickness greater than the first thickness.

17. The method of claim 15, wherein oxidizing the exposed portion of the first data metal layer comprises performing a plasma oxidation treatment or a thermal oxidation treatment.

18. The method of claim 15, wherein patterning the second data metal layer comprises
disposing a mask on the second data metal layer to cover a region at which the first contact pad is to be provided; and
selectively removing the second data metal layer using the mask to provide the second data metal pattern.

19. The method of claim 18, wherein oxidizing the exposed portion of the first data metal layer comprises oxidizing the exposed portion of the second data metal pattern to provide a second non-conductive metal oxide layer.

20. The method of claim 14, further comprising an organic insulation layer covering the first non-conductive metal oxide layer.
